(19) United States
(12) Patent Application Publication
(10) Pub. No.: US 2026/0323941 A1
(43) Pub. Date: Oct. 15, 2026

(54) MICROELECTRONIC DEVICES AND ASSOCIATED SYSTEMS AND METHODS

(71) Applicant: Micron Technology, Inc., Boise, ID (US)

(72) Inventor: Anna Maria Conti, Milano (IT)

(21) Appl. No.: 19/464,410

(22) Filed: Jan. 29, 2026

Related U.S. Application Data
(60) Provisional application No. 63/765,259, filed on Feb. 28, 2025.

(51) Int. Cl. H10B 43/27; H10B 80/00

(52) U.S. Cl. CPC H10B 43/27; H10B 80/00

(57) ABSTRACT

A microelectronic device structure includes a stack structure including tiers vertically stacked relative to one another and including a conductive structure and an insulative structure vertically neighboring the conductive structure. The stack structure further includes a first stadium structure and a second stadium structure having steps defined by horizontal ends of a group of the tiers. The second stadium structure vertically offset from the first stadium structure. The microelectronic device structure further includes an intermediate array region horizontally positioned between the first stadium structure and the second stadium structure having a first lateral width. The microelectronic device structure also includes an outer array region horizontally positioned between the first stadium structure and a horizontal end of the stack structure and having a second lateral width greater than the first lateral width, the intermediate array region and the outer array region including an array of memory cells.

### CROSS-REFERENCE TO RELATED APPLICATIONS

This application claims the benefit under 35 U.S.C. § 119(e) of U.S. Provisional Patent Application Ser. No. 63/765,259, filed Feb. 28, 2025, the disclosure of which is hereby incorporated herein in its entirety by this reference.

### TECHNICAL FIELD

Embodiments of the disclosure generally relate to microelectronic devices. In particular, embodiments of the disclosure relate to microelectronic devices including staircase structures, and to associated systems and methods.

### BACKGROUND

A continuing goal of the microelectronics industry has been to increase the memory density (e.g., the number of memory cells per memory die) of memory devices, such as non-volatile memory devices (e.g., NAND Flash memory devices). One way of increasing memory density in non-volatile memory devices is to utilize vertical memory array (also referred to as a “three-dimensional (3D) memory array”) architectures. A conventional vertical memory array includes vertical memory strings extending through openings in tiers of conductive structures (e.g., word line plates) and dielectric materials at each junction of the vertical memory strings and the conductive structures. Such a configuration permits a greater number of switching devices (e.g., transistors) to be located in a unit of die area (i.e., length and width of active surface consumed) by building the array upwards (e.g., longitudinally, vertically) on a die, as compared to structures with conventional planar (e.g., two-dimensional) arrangements of transistors.

Conventional 3D memory arrays include electrical connections between the conductive structures of the tiers and control logic devices (e.g., string drivers, word line drivers, access line drivers) within a base structure so that memory cells in the 3D memory array can be uniquely selected for writing, reading, or erasing operations. One method of forming such an electrical connection includes forming at least one so-called “staircase” (or “stair step”) structure at edges (e.g., horizontal ends) of the tiers. The staircase structure includes individual “steps” defining contact regions of the conductive structures. An assembly of the control logic devices may be provided in electrical communication with the steps of the staircase structure and, hence, the conductive structures and the memory cells of the 3D memory array, by way of routing and interconnect structures.

The memory density of the 3D memory array may be increased by increasing a number of tiers in the 3D memory array. Increasing the number of tiers may increase the number of routing structures through the array to access the different tiers, which may increase the complexity of the routing paths through the microelectronic devices.

### BRIEF DESCRIPTION OF THE DRAWINGS

FIG. 1 illustrates a perspective view of a portion of a microelectronic device structure, in accordance with embodiments of the disclosure;

FIG. 2 illustrates a vertical cross-sectional schematic view of a portion of a microelectronic device, in accordance with embodiments of the disclosure;

FIG. 3 illustrates a vertical cross-sectional schematic view of a portion of a microelectronic device, in accordance with embodiments of the disclosure;

FIG. 4 illustrates laterally aligned top-down views of portions of a microelectronic device, in accordance with embodiments of the disclosure; and

FIG. 5 is a schematic block diagram of an electronic system, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional non-volatile memory; conventional volatile memory), but also includes an application specific integrated circuit (ASIC) (e.g., a system on a chip (SoC)), a microelectronic device combining logic and memory, and a graphics processing unit (GPU) incorporating memory.

As used herein, the terms “configured” and “configuration” refers to a size, a shape, a material composition, a material distribution, orientation, and arrangement of at least one feature (e.g., one or more of at least one structure, at least one material, at least one region, at least one device) facilitating use of the at least one feature in a pre-determined way.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter means and includes to a degree that one skilled in the art would understand that the given parameter, property, or condition is met with a small degree of variance, such as within acceptable manufacturing tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, features (e.g., materials, structures, regions, circuitry, devices) described as “neighboring” one another means and includes features of the disclosed identity (or identities) that are located most proximate (e.g., closest to) one another. Additional features (e.g., additional regions, additional structures, additional regions, additional circuitry, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, relational terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the drawings. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, the term “and/or” means and includes any and all combinations of one or more of the associated listed items.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the drawings, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe-and Ni-based alloy, a Co-and Ni-based alloy, an Fe-and Co-based alloy, a Co-and Ni-and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric oxycarbide material (e.g., silicon oxycarbide (SiOₓC_{y})), at least one hydrogenated dielectric oxycarbide material (e.g., hydrogenated silicon oxycarbide (SiCₓO_{y}H_{z})), and at least one dielectric carboxynitride material (e.g., a silicon carboxynitride (SiOₓC_{z}N_{y})). In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials. In addition, each of a “semiconductor structure” and a “semiconductive structure” means and includes a structure formed of and including semiconductor material.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

As discussed above, vertical memory arrays facilitate a greater number of switching devices (e.g., transistors) to be located in a unit of die area (i.e., length and width of active surface consumed) by building the array upwards (e.g., longitudinally, vertically) on a die, as compared to structures with conventional planar (e.g., two-dimensional) arrangements of transistors. As the number of memory cells in a 3D memory array has increased, electrically connecting the memory cells of the 3D memory array to the assembly of control logic devices within the base structure has created sizing and spacing complications associated with the increased quantities and dimensions of routing and interconnect structures required to facilitate the electrical connection. In addition, the quantities, dimensions, and arrangements of different control logic devices employed within the base structure can also undesirably impede reductions to the size of a 3D memory array, increases to the storage density of the 3D memory array, and/or reductions in fabrication costs. Further increasing the number of control logic devices in a unit of die area may be achieved by changing an arrangement of the control logic devices. Embodiments of the disclosure facilitate greater numbers of control logic devices in a unit area as compared to conventional configurations, which facilitates enhanced memory array density while also decreasing the complexity of routing and interconnect structures through the microelectronic devices as compared to conventional configurations. Reducing the complexity of routing and interconnect structures may improve connections between components of the microelectronic devices (e.g., memory devices, such as 3D NAND Flash memory devices) of the disclosure and decrease failures (e.g., shorts, breaks, delaminations) relative to conventional microelectronic devices.

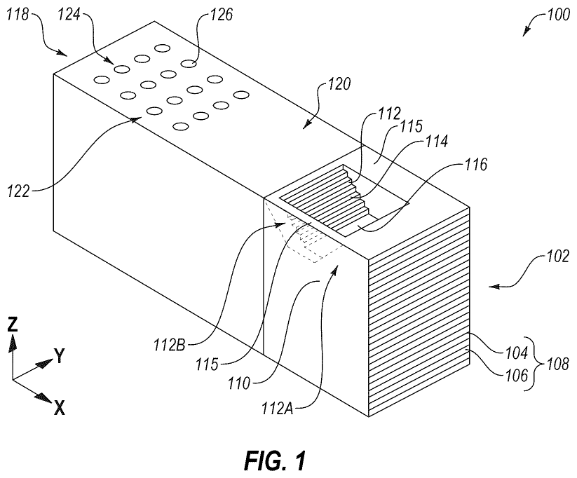

FIG. 1 illustrates a simplified, partial perspective view of a microelectronic device structure 100 of a microelectronic device (e.g., a memory device, such as a 3D NAND Flash memory device), in accordance with embodiments of the disclosure. As shown in FIG. 1, the microelectronic device structure 100 may be formed to include a stack structure 102 including a vertically alternating (e.g., in a Z-direction) sequence of insulative structures 104 and conductive structures 106 arranged in tiers 108. Each of the tiers 108 of the stack structure 102 may individually include at least one of the conductive structures 106 vertically neighboring (e.g., directly vertically adjacent) at least one of the insulative structures 104.

The insulative structure 104 of respective ones of the tier 108 of the stack structure 102 may be formed of and include at least one insulative material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). In some embodiments, the insulative structure 104 of each of the tiers 108 of the stack structure 102 is formed of and includes a dielectric oxide material, such as SiOₓ (e.g., SiO₂). The insulative structure 104 of each of the tiers 108 may be substantially homogeneous, or the insulative structure 104 of one or more (e.g., each) of the tiers 108 may be heterogeneous.

The conductive structure 106 of respective ones of the tiers 108 of the stack structure 102 may be formed of and include conductive material, such as one or more of at least one metal, at least one alloy, and at least one conductive metal-containing material (e.g., at least one conductive metal nitride, at least one conductive metal silicide, at least one conductive metal carbide, at least one conductive metal oxide), and at least one conductively doped semiconductor material (e.g., conductively doped polysilicon). In some embodiments, the conductive structures 106 are formed of and include tungsten (W). The conductive structures 106 of the tiers 108 of the stack structure 102 may be formed through a so-called “replacement gate” process wherein sacrificial material (e.g., dielectric nitride, such as SiN_{y}) of a preliminary stack structure is selectively removed (e.g., using a wet etchant comprising phosphoric acid (H₃PO₄)) relative to insulative material of the insulative structures 104, and then the resulting voids are filled with conductive material to form the conductive structures 106.

The stack structure 102 may be formed to include any desired number of the tiers 108. The stack structure 102 may include an odd number of the tiers 108 or may include an even number of the tiers 108. By way of non-limiting example, the stack structure 102 may be formed to include greater than or equal to sixteen (16) of the tiers 108, such as greater than or equal to thirty-two (32) of the tiers 108, greater than or equal to sixty-four (64) of the tiers 108, greater than or equal to one hundred twenty-eight (128) of the tiers 108, greater than or equal to two hundred fifty-six (256) of the tiers 108, or greater than or equal to five hundred twelve (512) of the tiers 108. However, the disclosure is not so limited, and may include a different quantity of the tiers 108 (e.g., a tier count that isn't a power of 2).

As shown in FIG. 1, the stack structure 102 may include one or more stadium structures 110 formed therein. The stadium structures 110 may respectively be bi-directional (e.g., configured to support two memory cell arrays horizontally neighboring opposing sides of thereof in the X-direction). In some embodiments, the bi-directionality of a respective stadium structure 110 may be facilitated or augmented by one or more (e.g., two) bridge regions 115 horizontally neighboring the stadium structure 110 in the Y-direction and horizontally extending completely across the stadium structure 110 in the X-direction. Each stadium structure 110 may include opposing staircase structures 112. The opposing staircase structures 112 of each stadium structure 110 may include a forward staircase structure 112A and a reverse staircase structure 112B. A phantom line extending from a top of the forward staircase structure 112A to a bottom of the forward staircase structure 112A may have a positive slope, and another phantom line extending from a top of the reverse staircase structure 112B to a bottom of the reverse staircase structure 112B may have a negative slope. In additional embodiments, one or more of the stadium structures 110 may individually exhibit a different configuration than that depicted in FIG. 1. As a non-limiting example, at least one stadium structure 110 may be modified to include a forward staircase structure 112A but not a reverse staircase structure 112B (e.g., the reverse staircase structure 112B may be absent), or at least one stadium structure 110 may be modified to include a reverse staircase structure 112B but not a forward staircase structure 112A (e.g., the forward staircase structure 112A may be absent). In additional embodiments, the stadium structures 110 may respectively be stairless (e.g., within the horizontal area of an individual stadium structure 110 contact structures may subsequently be formed to extend to and contact individual tiers 108 of the stack structure 102 associated with the stadium structure 110 in the absence of the opposing staircase structures 112). As described in further detail below, the total horizontal dimensions (e.g., a total horizontal area) of an individual stadium structure 110 are smaller than total string drivers bench horizontal dimensions (e.g., a total string drivers bench horizontal area).

The opposing staircase structures 112 (e.g., the forward staircase structure 112A and the reverse staircase structure 112B) of an individual stadium structure 110 respectively include steps 114 defined by edges (e.g., horizontal ends) of the tiers 108 of the stack structure 102. For the opposing staircase structures 112 of an individual stadium structure 110, each step 114 of the forward staircase structure 112A may have a counterpart step 114 within the reverse staircase structure 112B, having substantially the same geometric configuration (e.g., shape, dimensions), vertical position (e.g., in the Z-direction), and horizontal distance (e.g., in the X-direction) from a horizontal center (e.g., in the X-direction) of the stadium structure 110. In additional embodiments, at least one step 114 of the forward staircase structure 112A does not have a counterpart step 114 within the reverse staircase structure 112B, having substantially the same geometric configuration (e.g., shape, dimensions), vertical position (e.g., in the Z-direction), and/or horizontal distance (e.g., in the X-direction) from horizontal center (e.g., in the X-direction) of the stadium structure 110; and/or at least one step 114 of the reverse staircase structure 112B does not have a counterpart step 114 within the forward staircase structure 112A, having substantially the same geometric configuration (e.g., shape, dimensions), vertical position (e.g., in the Z-direction), and/or horizontal distance (e.g., in the X-direction) from horizontal center (e.g., in the X-direction) of the stadium structure 110.

Each stadium structure 110 (including the forward staircase structure 112A and the reverse staircase structure 112B thereof) within the stack structure 102 may individually partially define boundaries (e.g., horizontal boundaries, vertical boundaries) of a trench 116 at least partially vertically extending (e.g., in the Z-direction) through the stack structure 102. The portions of the stack structure 102 horizontally neighboring an individual stadium structure 110 may also partially define the boundaries of the trench 116 associated with the stadium structure 110. The trench 116 may vertically extend through tiers 108 of the stack structure 102 from an upper surface 120 (e.g., top) of the stack structure 102. The trench 116 may be substantially defined by tiers 108 of the stack structure 102 within a vertical span of the stadium structure 110, microelectronic device structure 100, or may also be defined, in-part, by additional tiers 108 of the stack structure 102 vertically overlying the stadium structure 110. Edges of the additional tiers 108 of the stack structure 102 may, for example, define one or more additional stadium structures vertically overlying and horizontally offset from the stadium structure 110. The trench 116 may be at least partially filled with one or more dielectric materials.

The stack structure 102 may be horizontally partitioned into blocks 118 by dielectric-filled slots that vertically extend completely through the stack structure 102. Each block 118 may include an array region 122 horizontally neighboring at least one of the stadium structures 110 in a first direction (e.g., the X-direction) and horizontally overlapping the stadium structure 110 in a second direction (e.g., the Y-direction) orthogonal to the first direction. The array region 122 may include an array 124 of cell pillar structures 126. The cell pillar structures 126 may vertically extend through the tiers 108 of the stack structure 102. The cell pillar structures 126 may each individually be formed of and include a stack of materials. By way of non-limiting example, each of the cell pillar structures 126 may be formed to include a charge-blocking material, such as first dielectric oxide material (e.g., SiOₓ, such as SiO₂; AlOₓ, such as Al₂O₃); a charge-trapping material, such as a dielectric nitride material (e.g., SiN_{y}, such as Si₃N₄); a tunnel dielectric material, such as a second dielectric oxide material (e.g., SiOₓ, such as SiO₂); a channel material, such as a semiconductor material (e.g., silicon, such as polycrystalline silicon); and a dielectric fill material (e.g., a dielectric oxide, a dielectric nitride, air). The charge-blocking material may be formed on or over surfaces of the conductive structures 106 and the insulative structures 104 of the tiers 108 of stack structure 102 at least partially defining horizontal boundaries of the cell pillar structures 126; the charge-trapping material may be horizontally surrounded by the charge-blocking material; the tunnel dielectric material may be horizontally surrounded by the charge-trapping material; the channel material may be horizontally surrounded by the tunnel dielectric material; and the dielectric fill material may be horizontally surrounded by the channel material.

Intersections of the cell pillar structures 126 and the conductive structures 106 of some of the tiers 108 (e.g., access line tiers) form strings of memory cells vertically extending through respective blocks 118 of the stack structure 102. In some embodiments, the memory cells formed at the intersections of the conductive structures 106 of the active access line tiers and the cell pillar structures 126 of some of the conductive structures 106 comprise so-called “MONOS” (metal-oxide-nitride-oxide-semiconductor) memory cells. In additional embodiments, the memory cells comprise so-called “TANOS” (tantalum nitride-aluminum oxide-nitride-oxide-semiconductor) memory cells, or so-called “BETANOS” (band/barrier engineered TANOS) memory cells, each of which are subsets of MONOS memory cells. In further embodiments, the memory cells comprise so-called “floating gate” memory cells including floating gates (e.g., metallic floating gates) as charge storage structures. The floating gates may horizontally intervene between central structures of the cell pillar structures 126 and the conductive structures 106 of different tiers 108 of the stack structure 102. In addition, intersections of the cell pillar structures 126 and the conductive structures 106 of some other of the tiers 108 (e.g., select gate tiers) of the stack structure 102 may define different select transistors (e.g., source-side select transistors, drain-side select transistors) coupled in series with the strings of memory cells.

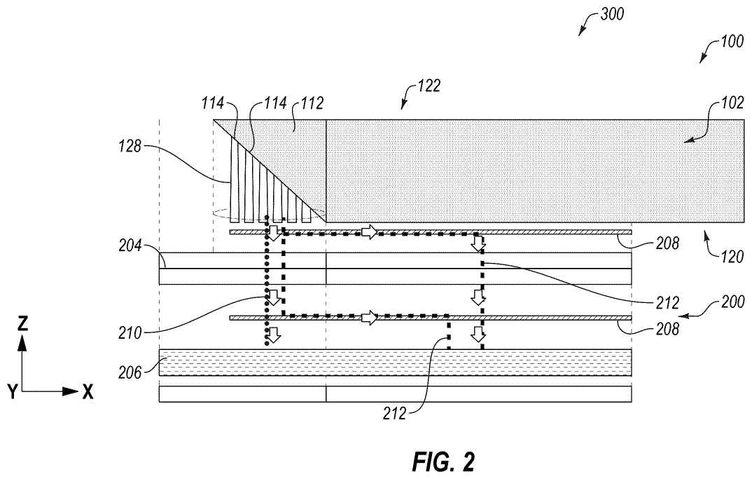

Referring next to FIG. 2, the microelectronic device structure 100 may be stacked on an additional microelectronic device structure 200 (e.g., a control circuitry structure) to form a microelectronic device 300 (e.g., a memory device, such as a 3D NAND Flash memory device). The microelectronic device structure 100 and the additional microelectronic device structure 200 may be attached (e.g., bonded) together through so-called “wafer-on-wafer” bonding techniques, wherein the microelectronic device structure 100 and the additional microelectronic device structure 200 are formed separately from one another, one of the microelectronic device structure 100 and the additional microelectronic device structure 200 (e.g., the microelectronic device structure 100 in FIG. 2) is vertically inverted, and then the microelectronic device structure 100 and the additional microelectronic device structure 200 are bonded to one another through dielectric-to-dielectric bonding and/or metal-to-metal bonding. The microelectronic device 300 may include a bonding interface region 204 between the microelectronic device structure 100 and the additional microelectronic device structure 200. In the embodiment shown in FIG. 2, the microelectronic device structures 100 are provided in a front-to-front (F2F) (also referred to as a “face-to-face”) arrangement relative to one another, wherein a front of the microelectronic device structure 100 proximate the upper surface 120 of the stack structure 102 is bonded to a front of the additional microelectronic device structure 200. In additional embodiments, the microelectronic device 300 is formed without bonding a separately formed microelectronic device structure 100 to a separately formed additional microelectronic device structure 200. For example, the microelectronic device 300 may be formed using a single wafer by progressively forming features described with respect to the microelectronic device structure 100 over features described with respect to the microelectronic device structure 200. In some such embodiments, the microelectronic device 300 may exhibit a so-called “circuitry under array” (CuA) architecture.

The microelectronic device 300 may include structures extending between the microelectronic device structure 100 and the additional microelectronic device structure 200 through the bonding interface region 204. At least some of the structures (e.g., conductive structures, such as contact structures) are configured to communicatively connect elements of the microelectronic device structure 100 to elements of the additional microelectronic device structure 200. For example, the microelectronic device structure 100 may include contact structures 128 respectively in contact with one of the conductive structures 106 (FIG. 1) of one of the tiers 108 of the stack structure 102 at an individual step 114 of one of the staircase structures 112; the additional microelectronic device structure 200 may include driver circuitry 206 (e.g., word line driver circuitry, string driver circuitry), and conductive pathways may be formed to extend from at least some of the contact structures 128 of the microelectronic device structure 100, through the bonding interface region 204, and to the driver circuitry 206 of the additional microelectronic device structure 200.

In some embodiments, the contact structures 128 (and, hence, the staircase structure(s) 112) of the microelectronic device structure 100 horizontally overlap (e.g., in the X-direction, in the Y-direction) the driver circuitry 206 of the additional microelectronic device structure 200 operatively associated therewith. Structures of the microelectronic device structure 100 and the additional microelectronic device structure 200 with a horizontal area of the staircase structure 112 of the microelectronic device structure 100 may effectively together form a direct path 210 that is substantially straight in a vertical direction (e.g., the Z-direction) from and between the microelectronic device structure 100 and the additional microelectronic device structure 200.

In other embodiments, conductive structures 208 are included in the microelectronic device structure 100 and/or the additional microelectronic device structure 200, and extend laterally (e.g., in the X-direction, in the Y-direction) across portions of the microelectronic device structure 100 and the additional microelectronic device structure 200. At least some of conductive structures 208 may be coupled to and horizontally extend (e.g., in the X-direction, in the Y-direction) from at least some of the contact structures 128 of the microelectronic device structure 100 and at least some of the control logic devices of the control logic devices of the additional microelectronic device structure 200. Accordingly, the conductive structures 208 may effectively form indirect paths 212 between contact structures 128 of the microelectronic device structure 100 and the driver circuitry 206 of the additional microelectronic device structure 200. In such embodiments, at least some of the driver circuitry 206 of the additional microelectronic device structure 200 is positioned outside the horizontal area of the staircase structures 112 of the microelectronic device structure 100, such as within the horizontal area of the array region 122 (FIG. 1) of the microelectronic device structure 100.

As the number of steps 114 in the staircase structures 112 increases, the number of conductive pathways between features (e.g., contact structures, routing structures) of the microelectronic device structure 100 and the additional microelectronic device structure 200 also increases. The number of direct paths 210 between features of the microelectronic device structure 100 and the additional microelectronic device structure 200 may be limited in the area. For example, to maintain isolation between the direct paths 210, a density of the direct paths 210 passing through the bonding interface region 204 may have a threshold number. As the number of steps 114 of an individual staircase structure 112 increases, some of the conductive pathways may extend into the horizontal area of the array region 122 (FIG. 1) of the microelectronic device structure 100 rather than being substantially confined within the horizontal area of the staircase structure 112 of the microelectronic device structure 100.

As discussed above, the array region 122 (FIG. 1) of the microelectronic device structure 100 may include cell pillar structures 126, which may be independently connected to other conductive structures (e.g., digit line structures, source structures, additional contact structures) of the microelectronic device structure 100 and/or the additional microelectronic device structure 200. Reducing the number of indirect paths 212 passing through the horizontal area of the array region 122 of the microelectronic device structure 100 may facilitate better connectivity between the cell pillar structures 126 and other conductive structures, and may provide additional area for additional microelectronic components to be positioned within the microelectronic device structure 100 and/or the additional microelectronic device structure 200.

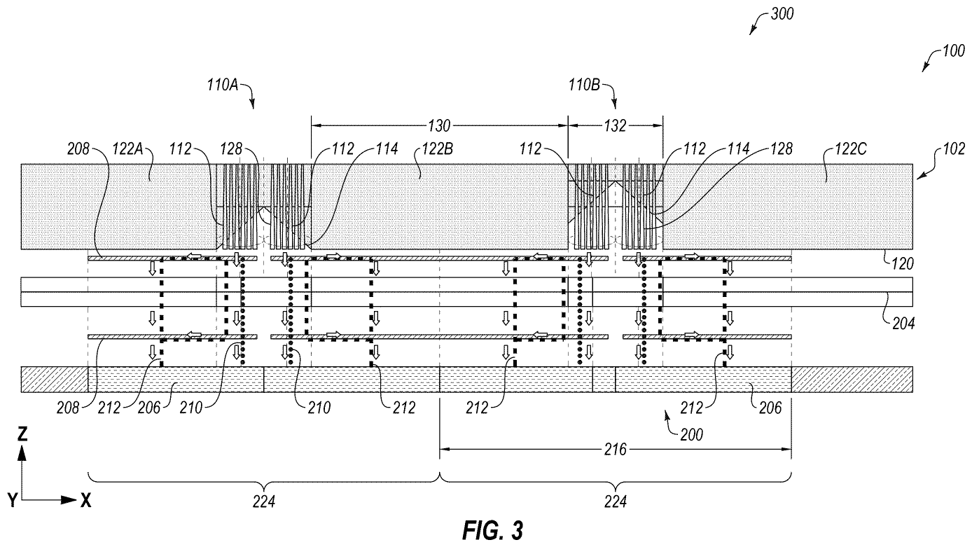

In some embodiments, multiple staircase structures 112 are distributed across the microelectronic device structure 100, in multiple stadium structures 110A, 110B, as illustrated in FIG. 3. The stadium structures 110A, 110B vertically extend to different depths within the stack structure 102 of the microelectronic device structure 100 than one another. For example, the steps 114 of the stadium structure 110A may be associated with different tiers 108 (FIG. 1) of the stack structure 102 than the steps 114 of the stadium structure 110B. As illustrated in FIG. 3, the staircase structures 112 of the stadium structure 110B may begin at a tier 108 (FIG. 1) that is vertically offset (e.g., relatively vertically deeper) (in the Z-direction) from all of the tiers 108 (FIG. 1) defining the steps 114 of the stadium structure 110A.

Distributing the staircase structures 112 into multiple different stadium structures 110A, 110B may reduce the number of steps 114 in each stadium structure 110A, 110B. Reducing the number of steps 114 in each stadium structure 110A, 110B may reduce the number of contact structures 128 extending from the steps 114 of each stadium structure 110A, 110B, and reduce the number of conductive pathways associated with a respective one of stadium structures 110A, 110B, and extending through the bonding interface region 204 between the microelectronic device structure 100 and the additional microelectronic device structure 200. Reducing the number of pathways extending through the bonding interface region 204 for an individual stadium structure 110A, 110B may reduce the number of (or even eliminate) the indirect paths 212 associated with the stadium structures 110A, 110B. Thus, employing multiple different stadium structures 110A, 110B may facilitate increasing the number of tiers 108 in the stack structure 102 without increasing the number of indirect paths 212 horizontally extending into the horizontal areas of array regions 122 (e.g., array regions 122A, 122B, 122C) of the microelectronic device structure 100. The distributed staircase structures 112 may reduce or eliminate the indirect paths 212 employing conductive structures 208 of the microelectronic device structure 100 and/or the additional microelectronic device structure 200.

As shown in FIG. 3, in some embodiments, array regions 122A, 122B, 122C of the microelectronic device structure 100 may horizontally alternate (e.g., in the X-direction) with the stadium structures 110A, 110B of the microelectronic device structure 100. For example, the stadium structures 110A, 110B may be horizontally interposed (e.g., in the X-direction) between outer array regions 122A, 122C, and an intermediate array region 122B may be horizontally interposed (e.g., in the X-direction) between the stadium structures 110A, 110B. Each of the outer array regions 122A, 122C and the intermediate array region 122B may include an array 124 (FIG. 1) of cell pillar structures 126 (FIG. 1) within a horizontal area thereof. In some embodiments, the horizontal size (e.g., width 130) of the intermediate array region 122B may be at least partially defined by the position of the driver circuitry 206 within the additional microelectronic device structure 200, such that the stadium structures 110A, 110B horizontally overlap (e.g., in the X-direction) the associated control logic devices.

In the embodiment illustrated in FIG. 3, the intermediate array region 122B of the microelectronic device structure 100 has a width 130 sufficient to substantially horizontally center (e.g., in the stadium structure 110A and the stadium structure 110B of the microelectronic device structure 100) relative to underlying driver regions 224 individually including some of the driver circuitry 206. For example, horizontal centerlines 214, in the X-direction of the stadium structures 110A, 110B may individually be substantially horizontally aligned, in the X-direction, with horizontal centerlines 214 of a respective driver region 224 including some of the driver circuitry 206. Respectively substantially horizontally centering the stadium structures 110A, 110B relative to an underlying driver region 224 may facilitate connections between the contact structures 128 operatively associated with the steps 114 of the stadium structure 110A and the driver circuitry 206 within the driver region 224.

An individual driver region 224 may have a horizontal width 216 (e.g., in the X-direction) that is greater than a horizontal width 132 (e.g., in the X-direction) of an individual stadium structure 110A, 110B horizontally overlapping the driver region 224. For example, the horizontal width 216 of one of the driver regions 224 may be at least about 2 times (2X) the horizontal width 132 of one of the stadium structures 110A, 110B, such as at least about 5 times (5X) the horizontal width 132 of one of the stadium structures 110A, 110B, or at least about 7 times (7X) the horizontal width 132 of one of the stadium structures 110A, 110B.

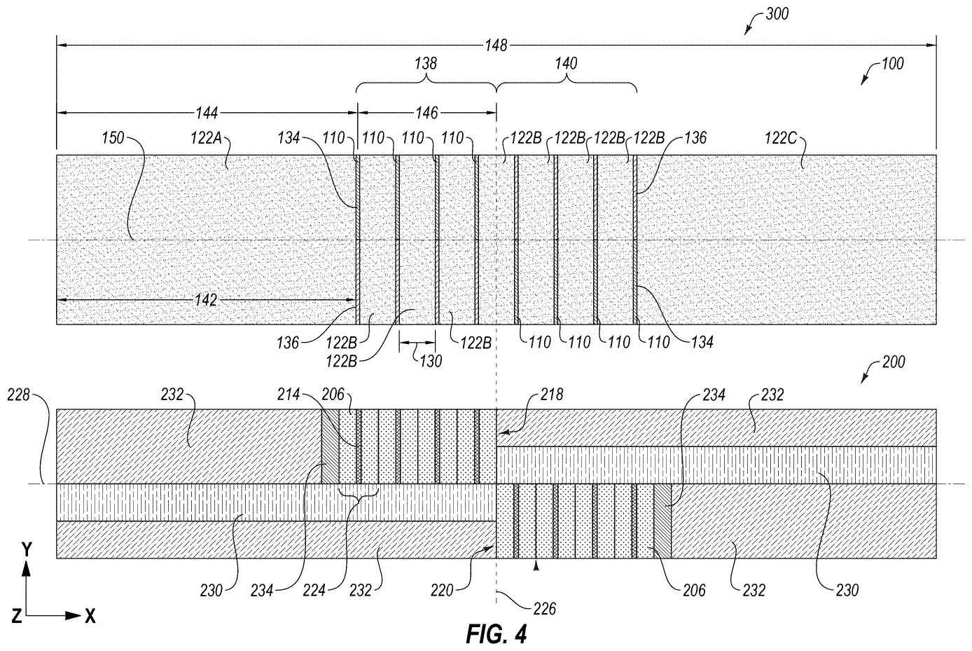

FIG. 4 illustrates a top-down view of each of the microelectronic device structure 100 and the additional microelectronic device structure 200 laterally aligned in the X-direction to illustrate the alignment of the different features of the microelectronic device structure 100 and the additional microelectronic device structure 200.

As illustrated in FIG. 4, the driver regions 224 of the additional microelectronic device structure 200 may be grouped together in a horizontal area near a lateral center (e.g., in the X-direction) of the additional microelectronic device structure 200. The driver regions 224 may be arranged in two groups 218, 220. A first group 218 and a second group 220 may extend in opposing lateral directions in both the Y-direction and the X-direction from a center line 226 and a center line 228. Thus, the driver circuitry 206 of the first group 218 may be positioned in a first quadrant of the additional microelectronic device structure 200 defined by the center line 226 and the center line 228, and the driver circuitry 206 of the second group 220 may be positioned within a third quadrant of the additional microelectronic device structure 200 defined by the center line 226 and the center line 228. The first quadrant and the third quadrant do not horizontally overlap in the X-direction or in the Y-direction. The first group 218 and the second group 220 may together form a “full bench” of the driver regions 224 (and, hence, of the driver circuitry 206) of the additional microelectronic device structure 200. For an individual driver region 224 within a respective group 218, 220 of the microelectronic device structure 200, the portion of the driver circuitry 206 therein may be operatively associated with an active portion 134 of one of the stadium structures 110 of the microelectronic device structure 100.

Within respective ones of the driver regions 224, driver devices (e.g., string drivers, word line drivers) thereof may be arranged in a row extending substantially linearly in the Y-direction. The driver devices may be double-gated driver devices, single-gated driver devices, or a combination thereof. The rows may be sufficiently close that respective ones of the groups 218, 220 of the driver regions 224 are continuous and substantially free of additional circuitry horizontally and vertically overlapping the driver circuitry 206 thereof.

In the embodiment illustrated in FIG. 4, each of the stadium structures 110 includes an active portion 134 and an inactive portion 136. The active portion 134 may include the contact structures 128 (FIGS. 2 and 3) connected to the conductive pathways through the microelectronic device structure 100 and the additional microelectronic device structure 200. The inactive portion 136 may be substantially free of the contact structures 128 within a horizontal area thereof, and the corresponding horizontal area between the inactive portion 136 of the stadium structures 110 and the additional microelectronic device structure 200 may be substantially free of the conductive pathways.

As further illustrated in FIG. 4, the stadium structures 110 are grouped, such that the active portion 134 of a first group 138 of stadium structures 110 is on a same lateral side (e.g., in the Y-direction) of the microelectronic device structure 100, and the active portions 134 of a second group 140 of stadium structures 110 are on a same lateral side (e.g., in the Y-direction) of the microelectronic device structure 100, where the active portions 134 of the first group 138 are on an opposite lateral side of the microelectronic device structure 100 from the active portions 134 of the second group 140. The stadium structures 110 of the first group 138 are each arranged adjacent to one another, such that none of the stadium structures 110 of the second group 140 are positioned between the stadium structures 110 of the first group 138. Similarly, the stadium structures 110 of the second group 140 are each arranged adjacent to one another, such that none of the stadium structures 110 of the first group 138 are positioned between the stadium structures 110 of the second group 140. The active portions 134 of the first group 138 may be positioned in a first quadrant of the microelectronic device structure 100 defined by the center line 226 and a center line 150, and the inactive portions 136 of the first group 138 may be positioned in a fourth quadrant of the microelectronic device structure 100 defined by the center line 226 and the center line 150. The active portion 134 of the second group 140 may be positioned within a third quadrant of the microelectronic device structure 100 defined by the center line 226 and the center line 150, and the inactive portion 136 of the second group 140 may be positioned within a second quadrant of the microelectronic device structure 100 defined by the center line 226 and the center line 150. Each driver region 224 of the driver circuitry 206 may correspond with an active portion 134 of one of the stadium structures 110 in the microelectronic device structure 100.

The two groups 218, 220 of the driver regions 224 may correspond to the groups 138, 140 of the stadium structures 110. For example, the first group 138 of the stadium structures 110 may be arranged such that the active portions 134 of the stadium structures 110 in the first group 138 are positioned vertically over and within the horizontal area of the driver regions 224 of the first group 218 of the driver regions 224. Similarly, the second group 140 of the stadium structures 110 may be arranged such that the active portion 134 of the stadium structures 110 in the second group 140 are positioned vertically over and within the horizontal area of the driver regions 224 of the second group 220. The portion of the additional microelectronic device structure 200 positioned vertically beneath and encompassing the horizontal area of the inactive portions 136 of the stadium structures 110 may be substantially free of driver circuitry 206.

As discussed above, the horizontal width 130 (e.g., in the X-direction) of an individual intermediate array region 122B may be defined, at least in part, by the horizontal width 216 (FIG. 3) (e.g., in the X-direction) of an individual control logic device. The horizontal width 130 of an individual intermediate array region 122B may be sufficient to position the stadium structures 110 separating the intermediate array regions 122B to vertically overlie and horizontally overlap the horizontal centerlines 214 of a respective driver region 224 including some of the driver circuitry 206. For example, the horizontal width 130 (e.g., in the X-direction) of respective ones of the intermediate array regions 122B may be less than or equal to the horizontal width (e.g., in the X-direction) of two (2) of the control logic devices of the driver circuitry 206 or the horizontal width (e.g., in the X-direction) of two (2) rows of control logic devices of the driver circuitry 206.

Block select circuitry 234 may be positioned on a distal end of each of the groups 218, 220 of driver regions 224 from the center line 226. The block select circuitry 234 may include block select devices or block select drivers. The block select circuitry 234 associated with the first group 218 of driver regions may be positioned in the first quadrant of the microelectronic device structure 200 and the block select circuitry 234 associated with the second group 220 of driver regions 224 may be positioned in the third quadrant of the microelectronic device structure 200. In the embodiment illustrated in FIG. 4, the block select circuitry 234 is positioned directly adjacent the respective first group 218 and second group 220 of driver regions 224. In some embodiments, the block select circuitry 234 may be separated from the respective first group 218 or second group 220 of driver regions 224. For example, the block select circuitry 234 may be positioned at an opposite end of the respective quadrant from the associated first group 218 or second group 220 of driver regions 224.

The outer array regions 122A, 122C may be relatively larger than the intermediate array regions 122B. As illustrated in FIG. 4, the outer array regions 122A, 122C respectively have a horizontal width 142 (e.g., in the X-direction) that is greater than the horizontal width 130 (e.g., in the X-direction) of respective ones of the individual intermediate array regions 122B. For example, the horizontal width 142 of the outer array region 122A may be within a range of about 2 times (2X) the horizontal width 130 of an intermediate array region 122B to about 10 times (10X) the horizontal width 130 of the intermediate array region 122B, such as from about 5 times (5X) the horizontal width 130 of the intermediate array region 122B to about 8 times (8X) the horizontal width 130 of the intermediate array region 122B. The horizontal width 142 may not be a natural number multiple of the horizontal width 130, for example, the horizontal width 142 may lie anywhere between 2 times (2X) the horizontal width 130 and 10 times (10X) the horizontal width 130, such as 2.8 times (2.8X) the horizontal width 130 or 7.3 times (7.3X) the horizontal width 130.

The stadium structures 110 may be arranged such that a last stadium structure 110 at a lateral end of a group of all of the stadium structures 110 is positioned a distance 144 from a lateral end of the microelectronic device structure 100 that is greater than a distance 146 from the center line 226 to the same last stadium structure 110. For example, the distance 144 may be at least about 2 times (2X) the distance 146, such as at least about 3 times (3X) the distance 146, or at least about 4 times (4X) the distance 146. The distance 144 may not be a natural number multiple of the distance 146. For example, the distance 144 may lie anywhere between different multiples of the distance 146, such as 2.8 times (2.8X) the distance 146 or 3.3 times (3.3X) the distance 146. The distance 144 may be within a range from about one-fourth (¼) of a total width 148 of the microelectronic device structure 100 to about one-half (½) of the total width 148 of the microelectronic device structure 100, such as from about one-third (⅓) of the total width 148 of the microelectronic device structure 100 to about one-half (½) of the total width 148 of the microelectronic device structure 100. The greater distance 144 between the outer stadium structures 110 and the lateral end of the stadium structures 110 may facilitate the stadium structures 110 being positioned relatively close to the center line 226, such that there is not a large discrepancy in a horizontal length of a lateral conductive structure, such as a word line, between any one of the outer stadium structures 110 and both lateral ends of the microelectronic device structure 100. Reducing a size discrepancy in a lateral conductive structure on both sides of any stadium structure 110 may result in more consistent performance of the connections between the lateral conductive structure and the stadium structure 110, at least due to the lateral conductive structures having similar resistance on both lateral sides of the stadium structure.

The portions of the additional microelectronic device structure 200 that are free of driver circuitry 206 may include additional circuitry region 230 and open region 232. The additional circuitry region 230 may extend laterally across the additional microelectronic device structure 200, and may include features, such as conductive structures, buffer devices (e.g., page buffer devices), or intermediate storage devices configured to form connections between or interface with one or more features of the additional microelectronic device structure 200.

The additional circuitry region 230 may extend under (e.g., vertically beneath and within a horizontal area of) at least a portion of each of the outer array regions 122A, 122C and the intermediate array regions 122B. For example, one additional circuitry region 230 may extend from or proximate a lateral end of the additional microelectronic device structure 200 to or proximate the center line 226 in a second quadrant of the additional microelectronic device structure 200 defined by the center line 226 and the center line 228. Another additional circuitry region 230 may extend from or proximate a lateral end of the additional microelectronic device structure 200 to or proximate the center line 226 in a fourth quadrant of the additional microelectronic device structure 200 defined by the center line 226 and the center line 228. Thus, the additional circuitry region 230 may extend under the intermediate array regions 122B between the inactive portions 136 of the stadium structures 110. In the embodiment illustrated in FIG. 4, the additional circuitry region 230 extends completely under each of the outer array regions 122A, 122C and the intermediate array regions 122B. This may facilitate direct connections between the cell pillar structures 126 in the array regions 122A, 122B, 122C and the additional circuitry region 230 without complicated lateral paths. The direct connections may improve the reliability of the connections and reduce the complexity of forming associated structures.

The open region 232 may be configured to house other circuitry, components, and devices that are not directly associated with the driver circuitry 206. For example, the open region 232 may include resistors, capacitors, diodes, inductors, access circuits, timer circuits, electro-static discharge circuits, sensors, detectors, among others. As illustrated in FIG. 4, positioning the driver regions 224 close together near the center line 226 may facilitate relatively large areas of the open region 232 with little to no segmentation. This may facilitate greater flexibility in the open region 232 and improved reliability of the circuits and devices included therein.

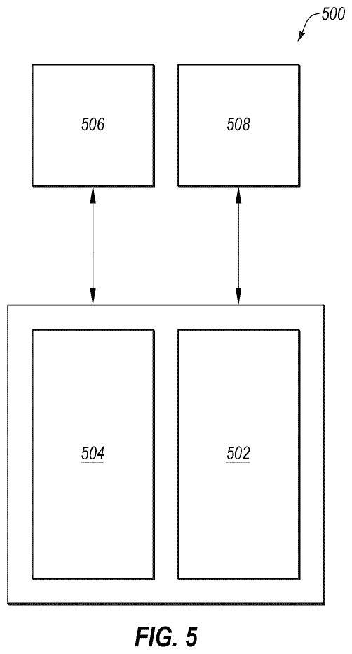

Microelectronic devices (e.g., the microelectronic device 300) of the disclosure may be included in embodiments of electronic systems of the disclosure. For example, FIG. 5 is a block diagram of an electronic system 500, in accordance with embodiments of the disclosure. The electronic system 500 may comprise, for example, a computer or computer hardware component, a server or other networking hardware component, a cellular telephone, a digital camera, a personal digital assistant (PDA), portable media (e.g., music) player, a Wi-Fi® or cellular-enabled tablet such as, for example, an iPAD® or SURFACE® tablet, an electronic book, a navigation device, etc. The electronic system 500 includes at least one memory device 502. The memory device 502 may include, for example, an embodiment of a semiconductor device package including one or more of the microelectronic devices previously described herein (e.g., the microelectronic device 300 previously described with reference to FIGS. 2 through 4).

The electronic system 500 may further include at least one electronic signal processor device 504 (often referred to as a “microprocessor”). The electronic signal processor device 504 may, optionally, include an embodiment of a microelectronic device previously described herein (e.g., the microelectronic device 300 previously described with reference to FIGS. 2 through 4). The electronic system 500 may further include one or more input devices 506 for inputting information into the electronic system 500 by a user, such as, for example, a mouse or other pointing device, a keyboard, a touchpad, a button, or a control panel. The electronic system 500 may further include one or more output devices 508 for outputting information (e.g., visual or audio output) to a user such as, for example, a monitor, a display, a printer, an audio output jack, a speaker, etc. In some embodiments, the input device 506 and the output device 508 may comprise a single touchscreen device that can be used both to input information to the electronic system 500 and to output visual information to a user. The input device 506 and the output device 508 may communicate electrically with one or more of the memory device 502 and the electronic signal processor device 504.

Thus, embodiments of the disclosure include a microelectronic device. The microelectronic device includes a first microelectronic device structure including a stack structure. The stack structure includes tiers vertically stacked relative to one another and respectively including a conductive structure and an insulative structure vertically neighboring the conductive structure. The stack structure further includes a first stadium structure having a first set of steps defined by horizontal ends of a first group of the tiers. The stack structure also includes a second stadium structure vertically offset from the first stadium structure and having a second set of steps defined by horizontal ends of a second group of the tiers. The first microelectronic device structure further includes an intermediate array region horizontally positioned between the first stadium structure and the second stadium structure in a first direction and having a first lateral width, the intermediate array region including an array of vertically extending strings of memory cells therein. The first microelectronic device structure also includes an outer array region horizontally positioned between the first stadium structure and a horizontal end of the stack structure and having a second lateral width greater than the first lateral width of the intermediate array region, the outer array region including an additional array of vertically extending strings of memory cells therein.

Another embodiment of the disclosure includes an electronic system. The system includes a memory device. The memory device includes an array structure. The array structure includes a first staircase structure at a first depth. The array structure further includes a second staircase structure at a second depth different from the first depth. The array structure also includes an array region positioned horizontally between the first staircase structure and the second staircase structure and vertically extending strings of memory cells therein. The memory device further includes a control circuitry structure vertically offset from and bonded to the array structure and. The control circuitry structure includes a first driver region horizontally positioned such that a first center line of the first driver region is positioned within a horizontal area of the first staircase structure of the array structure. The control circuitry structure further includes a second driver region horizontally neighboring the first driver region, the second driver region horizontally positioned such that a second centerline of the second driver region is positioned within a horizontal area of the second staircase structure of the array structure.

Other embodiments of the disclosure include a method of forming a microelectronic device. The method includes forming an array structure. The array structure including a stack structure including tiers respectively including conductive material and insulative material vertically adjacent the conductive material. The array structure further including a stadium structure comprising staircase structures respectively including steps defined by horizontal ends of a group of the tiers. The array structure also including an additional stadium structure horizontally offset from the stadium structure in a first direction and comprising additional staircase structures respectively including additional steps defined by horizontal ends of an additional group of the tiers. The array structure further including an array of cell pillars horizontally interposed between the stadium structure and the additional stadium structure in the first direction, the cell pillars respectively including semiconductor material vertically extending completely through the stack structure. The method further including forming a control circuitry structure comprising string driver devices. The method also including bonding the array structure to the control circuitry structure such that some of the string driver devices of the control circuitry structure horizontally overlap the stadium structure of the array structure in the first direction and such that some others of the string driver devices of the control circuitry structure horizontally overlap the additional stadium structure of the array structure in the first direction.

Embodiments of the disclosure may facilitate forming memory devices with greater numbers of tiers in the associated stack structures without segmenting the routing structures and open structures of an associated logic device. The embodiments of the disclosure may also reduce the complexity of the routing paths from the steps to the block select devices. These features may increase the memory density of the associated microelectronic devices. They may also improve reliability of the associated microelectronic devices and reduce the costs of building the microelectronic devices. This may also improve the reliability of an associated electronic device and reduce the costs of the associated electronic devices.

The embodiments of the disclosure described above and illustrated in the accompanying drawing figures do not limit the scope of the invention, since these embodiments are merely examples of embodiments of the invention, which is defined by the appended claims and their legal equivalents. Any equivalent embodiments are intended to be within the scope of this disclosure. Indeed, various modifications of the present disclosure, in addition to those shown and described herein, such as alternative useful combinations of the elements described, may become apparent to those skilled in the art from the description. Such modifications and embodiments are also intended to fall within the scope of the appended claims and their legal equivalents.

What is claimed is:

1. A microelectronic device, comprising:
a first microelectronic device structure comprising:
a stack structure including:
tiers vertically stacked relative to one another and respectively including a conductive structure and an insulative structure vertically neighboring the conductive structure;
a first stadium structure having a first set of steps defined by horizontal ends of a first group of the tiers; and
a second stadium structure vertically offset from the first stadium structure and having a second set of steps defined by horizontal ends of a second group of the tiers;
an intermediate array region horizontally positioned between the first stadium structure and the second stadium structure in a first direction and having a first lateral width, the intermediate array region including an array of vertically extending strings of memory cells therein; and
an outer array region horizontally positioned between the first stadium structure and a horizontal end of the stack structure and having a second lateral width greater than the first lateral width of the intermediate array region, the outer array region including an additional array of vertically extending strings of memory cells therein.

2. The microelectronic device of claim 1, further comprising a second microelectronic device structure bonded to the first microelectronic device structure and comprising control logic circuitry including driver circuitry.

3. The microelectronic device of claim 2, wherein at least one step of the first set of steps is operatively connected to the driver circuitry through a conductive path within a horizontal area of the first stadium structure of the first microelectronic device structure and vertically extending through a bonding interface region between the first microelectronic device structure and the second microelectronic device structure.

4. The microelectronic device of claim 3, wherein a portion of the driver circuitry of the second microelectronic device structure horizontally overlaps the first set of steps of the first stadium structure of the first microelectronic device structure.

5. The microelectronic device of claim 2, wherein the first microelectronic device structure further includes at least one routing structure vertically interposed between the stack structure and the second microelectronic device structure and horizontally extending across one or more the outer array region and the intermediate array region.

6. The microelectronic device of claim 2, wherein the driver circuitry of the second microelectronic device structure comprises string driver circuitry.

7. The microelectronic device of claim 6, wherein:
the first stadium structure is positioned within a horizontal area of a first region of the string driver circuitry; and
the second stadium structure is positioned within a horizontal area of a second region of the string driver circuitry.

8. The microelectronic device of claim 1, wherein the second lateral width of the outer array region is at least about five times (5X) the first lateral width of the intermediate array region.

9. The microelectronic device of claim 1, where the first stadium structure comprises a first active portion and a first inactive portion horizontal offset from the first active portion in a second direction perpendicular to the first direction.

10. The microelectronic device of claim 9, wherein the second stadium structure comprises a second active portion and a second inactive portion, wherein the second active portion of the second stadium structure is positioned on an opposite side in the second direction of a horizontal center line of the first microelectronic device structure from the first active portion of the first stadium structure.

11. An electronic system, comprising:
a memory device comprising:
an array structure comprising:
a first staircase structure at a first depth;
a second staircase structure at a second depth different from the first depth; and
array region positioned horizontally between the first staircase structure and the second staircase structure and vertically extending strings of memory cells therein;
a control circuitry structure vertically offset from and bonded to the array structure and comprising:
a first driver region horizontally positioned such that a first center line of the first driver region is positioned within a horizontal area of the first staircase structure of the array structure; and
a second driver region horizontally neighboring the first driver region, the second driver region horizontally positioned such that a second center line of the second driver region is positioned within a horizontal area of the second staircase structure of the array structure.

12. The electronic system of claim 11, wherein the first staircase structure of the array structure includes an active region and an inactive region.

13. The electronic system of claim 12, wherein the control circuitry structure includes a routing structure horizontal extending within a same vertical plane as the first driver region, the routing structure horizontal extending through a horizontal area of the inactive region of the first staircase structure.

14. The electronic system of claim 11, wherein the control circuitry structure is divided into four quadrants defined by a first horizontal center line in a first horizontal direction and a second horizontal center line in a second horizontal direction orthogonal to the first horizontal direction.

15. The electronic system of claim 14, wherein the first driver region of the control circuitry structure is positioned within a first quadrant of the four quadrants, and the second driver region of the control circuitry structure is positioned within a third quadrant of the four quadrants, where the third quadrant does not horizontally overlap the first quadrant in the first horizontal direction or the second horizontal direction.

16. The electronic system of claim 14, wherein:
a second quadrant of the four quadrants includes a first routing structure extending from the first horizontal center line to a first lateral end of the control circuitry structure; and
a fourth quadrant of the four quadrants includes a second routing structure extending from the first horizontal center line to a second lateral end of the control circuitry structure opposite the first lateral end.

17. The electronic system of claim 16, wherein the first routing structure is continuous between the first horizontal center line and the first lateral end of the control circuitry structure.

18. A method of forming a microelectronic device, comprising:
forming an array structure comprising:
a stack structure including tiers respectively including conductive material and insulative material vertically adjacent the conductive material;
a stadium structure comprising staircase structures respectively including steps defined by horizontal ends of a group of the tiers;
an additional stadium structure horizontally offset from the stadium structure in a first direction and comprising additional staircase structures respectively including additional steps defined by horizontal ends of an additional group of the tiers; and
an array of cell pillars horizontally interposed between the stadium structure and the additional stadium structure in the first direction, the cell pillars respectively including semiconductor material vertically extending completely through the stack structure;
forming a control circuitry structure comprising string driver devices; and
bonding the array structure to the control circuitry structure such that some of the string driver devices of the control circuitry structure horizontally overlap the stadium structure of the array structure in the first direction and such that some others of the string driver devices of the control circuitry structure horizontally overlap the additional stadium structure of the array structure in the first direction.

19. The method of claim 18, further comprising bonding the array structure to the control circuitry structure such that:
one of the two of the string driver devices of the control circuitry structure also horizontally overlaps the array of cell pillars in the first direction; and
one of the two other of the string driver devices of the control circuitry structure also horizontally overlaps the array of cell pillars in the first direction.

20. The method of claim 18, further comprising forming the control circuitry structure comprising to further comprise page buffer devices horizontally neighboring the string driver devices in a second direction orthogonal to the first direction.
